(19) United States
(12) Patent Application Publication
(10) Pub. No.: US 2016/0190318 A1
(43) Pub. Date: Jun. 30, 2016

(54) SEMICONDUCTOR DEVICE AND MANUFACTURING METHOD THEREOF

(71) Applicant: TAIWAN SEMICONDUCTOR MANUFACTURING CO., LTD., Hsinchu (TW)

(72) Inventors: Chia-Hsin CHEN, Hsinchu (TW); Chih-Lin WANG, Zhubei City (TW); Kang-Min KUO, Zhubei City (TW)

(21) Appl. No.: 14/800,899

(22) Filed: Jul. 16, 2015

Related U.S. Application Data
(60) Provisional application No. 62/098,206, filed on Dec. 30, 2014.

(51) Int. Cl. H01L 29/78; H01L 21/8234; H01L 27/088

(52) U.S. Cl. CPC H01L 29/7848; H01L 27/088; H01L 21/823418

(57) ABSTRACT

A semiconductor device includes a substrate, first strain-inducing source and drain structures, a first gate structure, a first channel region, second strain-inducing source and drain structures, a second gate structure, and a second channel region. At least one of the first strain-inducing source and drain structures has a first proximity to the first channel region. At least one of the second strain-inducing source and drain structures has a second proximity to the second channel region. The second proximity is different from the first proximity.

### PRIORITY CLAIM AND CROSS-REFERENCE

This application claims priority to U.S. Provisional Application Ser. No. 62/098,206, filed Dec. 30, 2014, which is herein incorporated by reference.

### BACKGROUND

The semiconductor integrated circuit (IC) industry has experienced rapid growth. Technological advances in IC materials and design have produced generations of ICs where each generation has smaller and more complex circuits than the previous generation. To enhance the performance of ICs, strained silicon has been used to enhance carrier mobility and improve device performance. Strained silicon is a layer of silicon in which the silicon atoms are stretched beyond their normal interatomic distance. Moving these silicon atoms farther apart reduces the atomic forces that interfere with the movement of electrons through the transistors and thus better mobility, resulting in better chip performance and lower energy consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for manufacturing a semiconductor device in accordance with some embodiments of the present disclosure.

FIGS. 2-7 are cross-sectional views of a semiconductor device at various stages of fabrication in accordance with some embodiments of the method of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

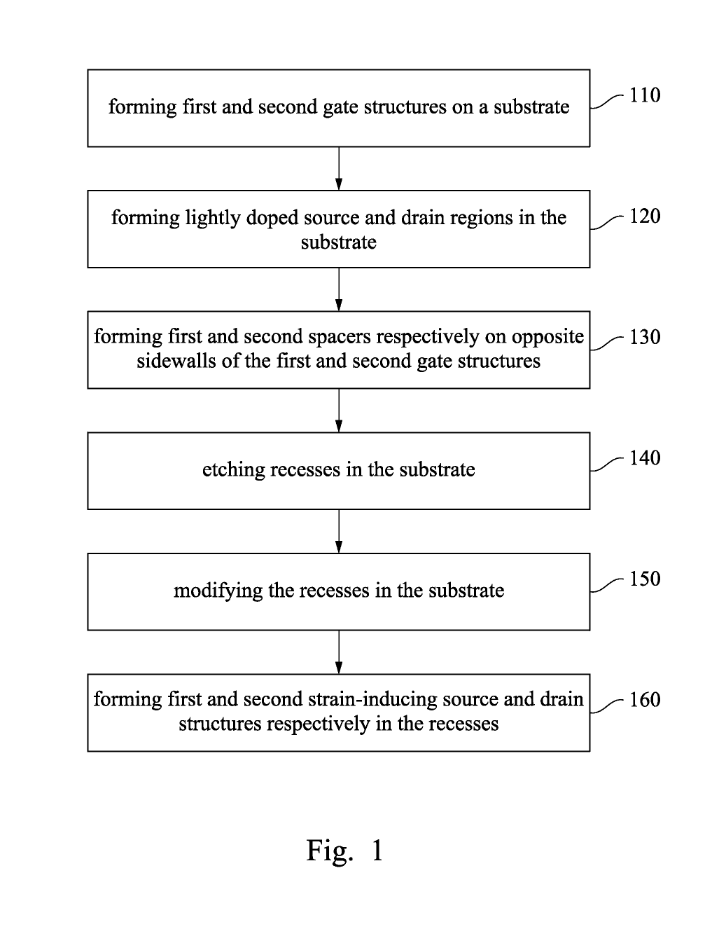

FIG. 1 is a flowchart of a method for manufacturing a semiconductor device in accordance with some embodiments of the present disclosure. The method begins with block 110 in which first and second gate structures are formed on a substrate. The method continues with block 120 in which lightly doped source and drain regions are formed in the substrate. The method continues with block 130 in which first and second spacers are formed respectively on opposite sidewalls of the first and second gate structures. The method continues with block 140 in which recesses are etched in the substrate. The method continues with block 150 in which the recesses in the substrate are modified. The method continues with block 160 in which first and second strain-inducing source and drain structures are formed respectively in the recesses.

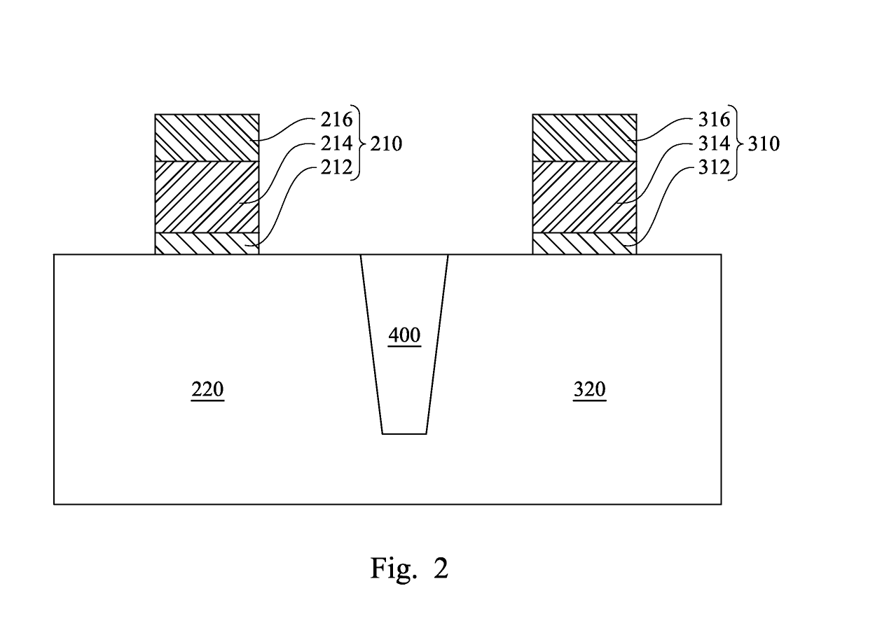

FIGS. 2-7 are cross-sectional views of a semiconductor device at various stages of fabrication in accordance with some embodiments of the method of FIG. 1. It is understood that FIGS. 2-7 have been simplified for a better understanding of the embodiments of the present disclosure. Accordingly, additional processes may be provided before, during, and after the method of FIG. 1, and some other processes may be briefly described herein.

Reference is made to FIG. 2. A first gate structure 210 and a second gate structure 310 are formed on a substrate. The substrate is made of a semiconductor material, such as silicon. In some embodiments, the substrate may include an epitaxial layer. For example, the substrate may have an epitaxial layer overlying a bulk semiconductor. Furthermore, the substrate may include a semiconductor-on-insulator (SOI) structure, such as a buried dielectric layer. Alternatively, the substrate may include a buried dielectric layer, such as a buried oxide (BOX) layer. The substrate may be formed by a method referred to as separation by implantation of oxygen (SIMOX) technology, wafer bonding, or selective epitaxial growth (SEG).

The substrate has a first active region 220 and a second active region 320. The first and second active regions 220 and 320 will be used for components of active devices, such as n-channel metal-oxide-semiconductor field-effect transistors (n-channel MOSFETs), p-channel MOSFETs or combinations thereof, to be formed later. Therefore, the first gate structure 210 and the second gate structure 310 are formed respectively on the first active region 220 and the second active region 320. Formation of the first and second active regions 220 and 320 may include implantation of dopants into the substrate. If n-channel MOSFETs are designed to be formed on the first and second active regions 220 and 320, p-wells are formed in the first and second active regions 220 and 320. If p-channel MOSFETs are designed to be formed on the first and second active regions 220 and 320, n-wells are formed in the first and second active regions 220 and 320.

If the substrate is made of a Group IV semiconductor material, such as silicon, the dopants can be acceptors from Group III or donors from Group V elements. For example, boron (B), aluminium (Al), indium (In), gallium (Ga), or combinations thereof, having three valence electrons, can be used as the dopants to form a p-well in the substrate when the substrate is made of a Group IV semiconductor material with four valence electrons. On the other hand, phosphorus (P), arsenic (As), antimony (Sb), bismuth (Bi), or combinations thereof, having five valence electrons, can be used as the dopants to form an n-well in the substrate when the substrate is made of a Group IV semiconductor material with four valence electrons.

At least one shallow trench isolation (STI) structure 400 is formed in the substrate for electrically isolating the first and second active regions 220 and 320 from each other. Formation of the STI structure 400 may include etching a trench in the substrate and filling the trench with at least one insulator material, such as silicon oxide, silicon nitride, silicon oxynitride, or combinations thereof. In some embodiments, the STI structure 400 may be created using a process sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical planarization (CMP) to etch back, and using nitride stripping to leave the STI structure 400.

The first gate structure 210 includes a gate dielectric layer 212 and a gate electrode layer 214. The second gate structure 310 includes a gate dielectric layer 312 and a gate electrode layer 314. In some embodiments, the gate dielectric layers 212 and 312 are made of an oxide material, such as silicon oxide. The gate dielectric layers 212 and 312 are formed by, for example, thermal oxidation, chemical vapor deposition (CVD), plasma-enhanced chemical vapor deposition (PECVD), low-pressure chemical vapor deposition (LPCVD), or combinations thereof.

In some embodiments, the gate dielectric layers 212 and 312 are made of a high-κ dielectric material. The high-κ dielectric material is a material having a dielectric constant that is greater than a dielectric constant of silicon dioxide (SiO₂), which is approximately 4. For example, the high-κ dielectric material may include hafnium dioxide (HfO₂), which has a dielectric constant that is in a range from approximately 18 to approximately 40. Alternatively, the high-κ material may include one of ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof.

The gate electrode layers 214 and 314 are made of, for example, polycrystalline silicon. The gate electrode layers 214 and 314 are formed by, for example, chemical vapor deposition (CVD), plasma-enhanced chemical vapor deposition (PECVD), low-pressure chemical vapor deposition (LPCVD), or combinations thereof. For example, silane (SiH₄) may be used as a chemical gas in a CVD process to form the gate electrode layers 214 and 314. The gate electrode layers 214 and 314 may have a thickness in a rang from about 400 Angstroms(Å) to about 800 Angstroms(Å).

In some embodiments, the first gate structure 210 may further include a hard mask layer 216 formed on the gate electrode layer 214, and the second gate structure 310 may further include a hard mask layer 316 formed on the gate electrode layer 314. The hard mask layers 216 and 316 are made of a dielectric material, such as silicon oxide, silicon nitride, silicon oxynitride, or combinations thereof. The hard mask layers 216 and 316 are formed by, for example, chemical vapor deposition (CVD), plasma-enhanced chemical vapor deposition (PECVD), low-pressure chemical vapor deposition (LPCVD), or combinations thereof. The hard mask layers 216 and 316 may have a thickness in a range from about 100 Angstroms(Å) to about 400 Angstroms(Å).

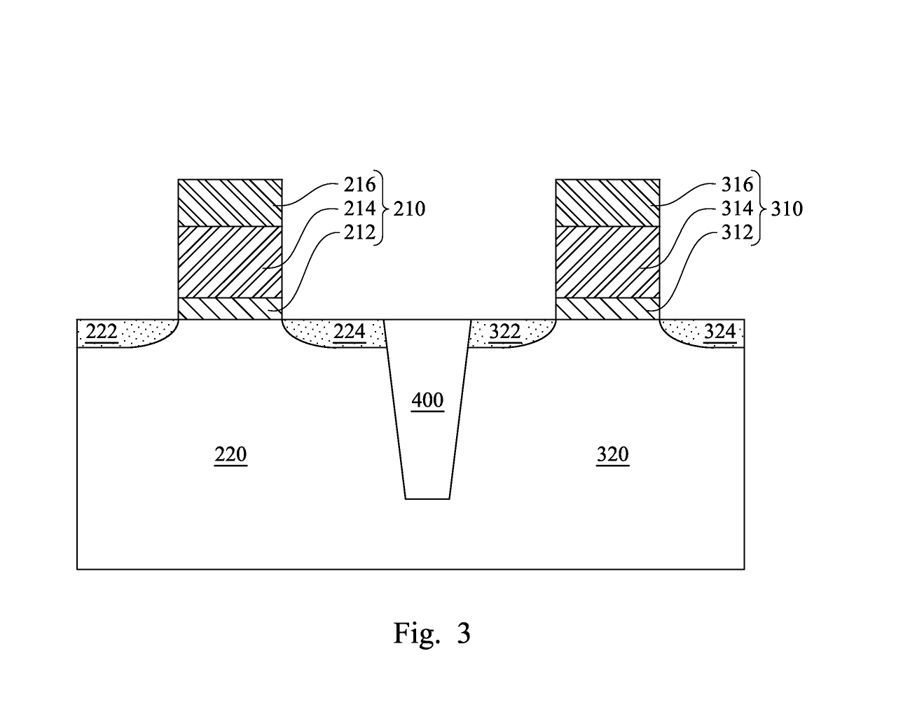

Reference is made to FIG. 3. An implantation process is performed to form lightly doped source and drain regions 222, 224, 322, and 324 in the substrate. The lightly doped source and drain regions 222 and 224 are disposed on opposite sides of the first gate structure 210, and the lightly doped source and drain regions 322 and 324 are disposed on opposite sides of the second gate structure 310. If n-channel metal-oxide-semiconductor field-effect transistors (n-channel MOSFETs) are designed to be formed on the first and second active regions 220 and 320, n-type dopants, such as phosphorus (P), arsenic (As), antimony (Sb), bismuth (Bi), or combinations thereof, are utilized to form the lightly doped source and drain regions 222, 224, 322, and 324. If p-channel MOSFETs are designed to be formed on the first and second active regions 220 and 320, p-type dopants, such as boron (B), aluminium (Al), indium (In), gallium (Ga), or combinations thereof, are utilized to form the lightly doped source and drain regions 222, 224, 322, and 324.

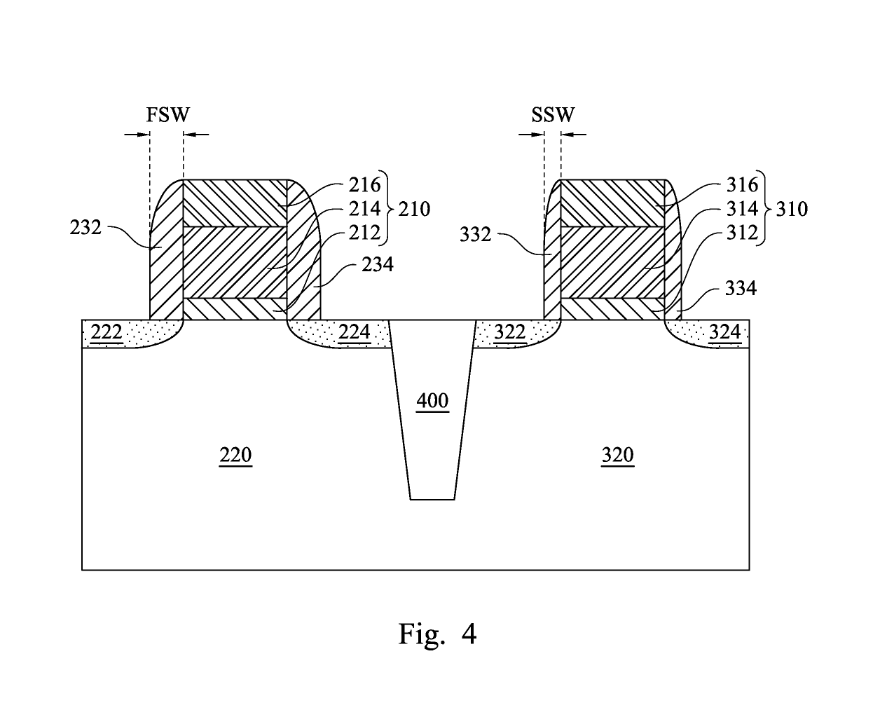

Reference is made to FIG. 4. First spacers 232 and 234 are formed on opposite sidewalls of the first gate structure 210, and second spacers 332 and 334 are formed on opposite sidewalls of the second gate structure 310. The first and second spacers 232, 234, 332, and 334 are made of a dielectric material, such as silicon nitride, silicon oxide, silicon oxynitride, or combinations thereof. In some embodiments, at least one of the first and second spacers 232, 234, 332, and 334 has an oxide-nitride-oxide (ONO) structure, that is, a silicon nitride layer disposed in between two silicon oxide layers.

At least one of the first spacers 232 and 234 has a spacer width (or spacer thickness) FSW, and at least one of the second spacers 332 and 334 has a second spacer width (or spacer thickness) SSW. The first spacer width FSW is different from the second spacer width SSW to have different initial proximity control. The first and second spacers 232, 234, 332, and 334 are formed by, for example, one or more deposition processes, photolithography processes, and etching processes (for example, anisotropic etching processes). The first spacer width FSW and the second spacer width SSW may be controlled by, for example, adjusting etching time.

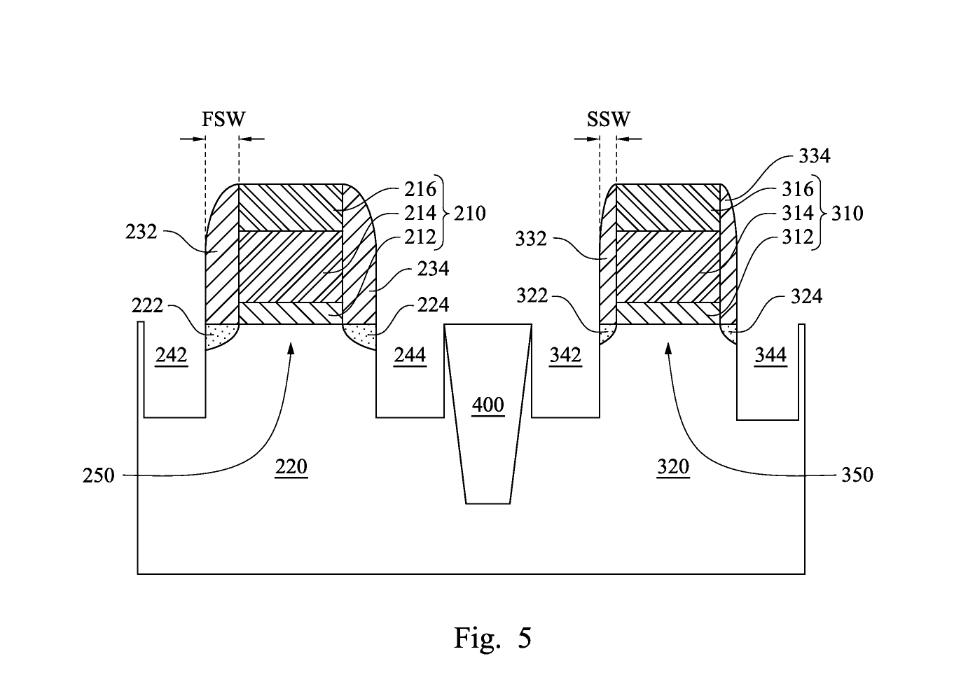

Reference is made to FIG. 5. An etching process is performed to etch recesses 242, 244, 342, and 344 in the substrate. In some embodiments, the etching process may include a dry etching process that utilizes a combination of HBr/Cl₂/O₂/He. The dry etching process removes portions of the substrate that are unprotected or exposed. The first and second spacers 232, 234, 332, and 334 and the hard mask layers 216 and 316 protect the first and second gate structures 210 and 310 during the dry etching process.

The recesses 242, 244, 342, and 344 have substantially vertical sidewalls that are aligned with the first and second spacers 232, 234, 332, and 334 due to the directional/anisotropic etching. In some embodiments, at least one of the recesses 242, 244, 342, and 344 has a depth in a range from about 100 Angstroms(Å) to about 250 Angstroms(Å). As a result, proximities of the recesses 242 and 244 to the first gate structure 210 are respectively limited by the first spacer widths FSW of the first spacers 232 and 234, and proximities of the recesses 342 and 344 to the second gate structure 310 are respectively limited by the second spacer widths SSW of the second spacers 332 and 334. Since the first spacer width FSW is different from the second spacer width SSW, the proximity of at least one of the recesses 242 and 244 to the first gate structure 210 is different from the proximity of at least one of the recesses 342 and 344 to the second gate structure 310. In some embodiments, the proximity of at least one of the recesses 242 and 244 to the first gate structure 210 is less than the proximity of at least one of the recesses 342 and 344 to the second gate structure 310. That is, a distance from at least one of the recesses 242 and 244 to the first gate structure 210 is greater than a distance from at least one of the recesses 342 and 344 to the second gate structure 310. Furthermore, a distance between the recesses 242 and 244 is different from a distance between the recesses 342 and 344. In some embodiments, the distance between the recesses 242 and 244 is greater than the distance between the recesses 342 and 344.

A first channel region 250 and a second channel region 350 are disposed in the substrate. The first channel region 250 is disposed under the first gate structure 210 and between the recesses 242 and 244. The second channel region 350 is disposed under the second gate structure 310 and between the recesses 342 and 344. Proximity of at least one of the recesses 242 and 244 to the first channel region 250 is different from proximity of at least one of the recesses 342 and 344 to the second channel region 350. In some embodiments, the proximity of at least one of the recesses 242 and 244 to the first channel region 250 is less than the proximity of at least one of the recesses 342 and 344 to the second channel region 350. That is, a distance from at least one of the recesses 242 and 244 to the first channel region 250 is greater than a distance from at least one of the recesses 342 and 344 and the second channel region 350.

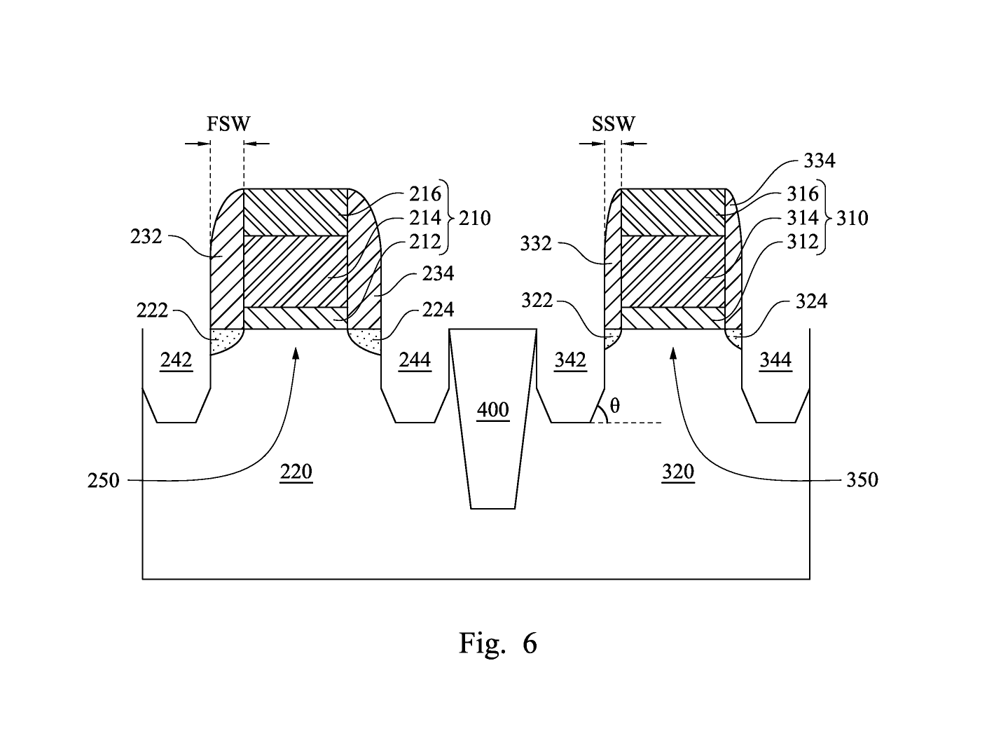

Reference is made to FIG. 6. Another etching process is performed to modify the recesses 242, 244, 342, and 344 in the substrate. The etching process may include a dry etching process that utilizes a combination of HBr/O₂/He. The dry etching process may be tuned so that the sidewalls of the recesses 242, 244, 342, and 344 are tapered, as shown in FIG. 6. In some embodiments, a bias voltage may be tuned to have the tapered sidewalls. At least one of the tapered sidewalls of at least one of the recesses 242, 244, 342, and 344 has a tapered angle θ in a range from about 50° to about 70°. The tapered angle θ is measured with respect to an axis that is parallel with the surface of the substrate. At least one of the recesses 242, 244, 342, and 344 has an overall depth in a range from about 500 Angstroms(Å) to about 600 Angstroms(Å).

In some embodiments, an implantation process may be optionally performed before formation of the recesses 242, 244, 342, and 344. The implantation process implants dopants which can enhance or retard etching rate of subsequent etching processes. For example, the implantation process may implant arsenic to enhance the etching rate of the subsequent etching processes. The arsenic dopants are implanted into the substrate with an energy range from about 1 keV to about 10 keV and with a dose range from about 1E14 cm⁻² to about 3E15 cm⁻². Furthermore, the arsenic dopants may be implanted into the substrate with a tile angle in a range from about 0° to about 25° with respect to a direction normal to the substrate. Alternatively, the implantation process may implant BF₂ to retard the etching rate of the subsequent etching processes. The BF₂ dopants are implanted into the substrate with an energy range from about 0.5 keV to about 5 keV and with a dose range from about 1E14 cm⁻² to about 3E15 cm⁻². Furthermore, the BF₂ dopants may be implanted into the substrate with a tile angle in a range from about 0° to about 25° with respect to a direction normal to the substrate.

Then, the recesses 242, 244, 342, and 344 are formed by a selective wet etching process or a dry etching process followed by a selective wet etching process. In the selective wet etching process, a dopant selective wet etchant, such as tetra-methyl ammonium hydroxide (TMAH) solution, may be used. The TMAH solution has a volume concentration in a range from about 1% to about 10% and has a temperature in a range from about 15° C. to about 50° C. The etching rate, including a lateral etching rate, of the substrate is affected by factors including type of dopants implanted and concentration of the dopants in the implanted regions. For example, if arsenic ions are used as the dopants, then the lateral etching rate is greater than if boron ions are used as the dopants. The concentration of the dopants is correlated to the dose of the dopants used in the implantation process.

In other words, the etching rate (including the lateral etching rate) of the implanted portions of the substrate are correlated to the type and the dose of the dopants used in the implantation process. These factors may also affect the profile of recesses 242, 244, 342, and 344.

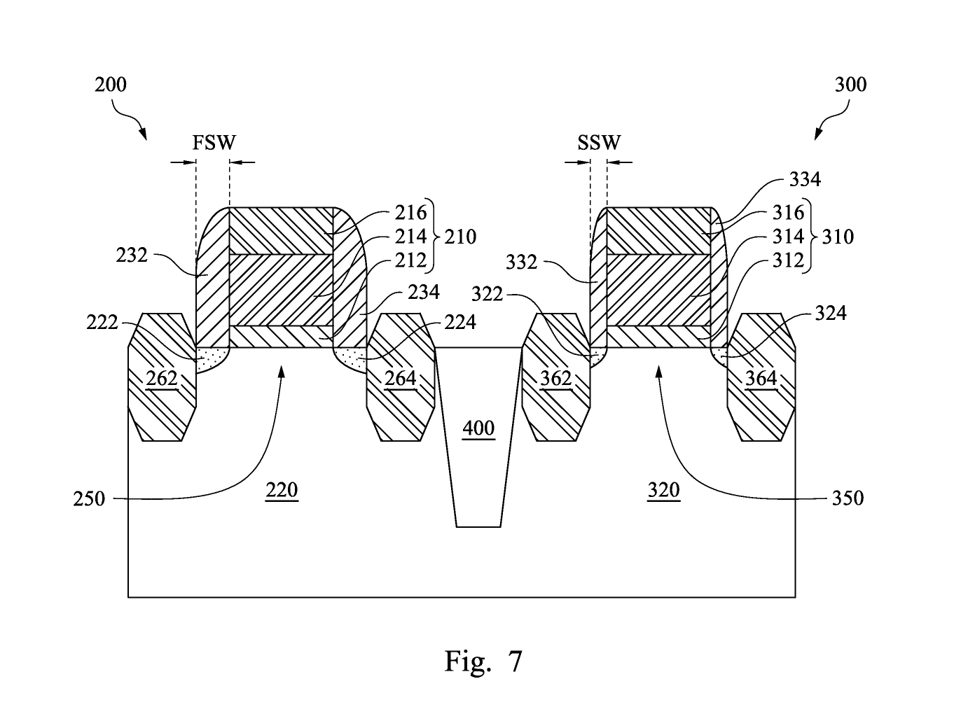

Reference is made to FIG. 7. First and second strain-inducing source and drain structures 262, 264, 362, and 364 are formed respectively at least partially in the recesses 242, 244, 342, and 344 (shown in FIG. 6). In some embodiments, the first and second strain-inducing source and drain structures 262, 264, 362, and 364 are formed by, for example, a selective-epitaxial-growth (SEG) process.

As shown in FIG. 7, a first transistor 200 and a second transistor 300 are formed. The first transistor 200 includes the first gate structure 210, the lightly doped source and drain regions 222 and 224, the first spacers 232 and 234, the first channel region 250, and the first strain-inducing source and drain structures 262 and 264. The second transistor 300 includes the second gate structure 310, the lightly doped source and drain regions 322 and 324, the second spacers 332 and 334, the second channel region 350, and the second strain-inducing source and drain structures 362 and 364.

In the embodiments where the first and second transistors 200 and 300 are both p-channel metal-oxide-semiconductor field-effect transistors (p-channel MOSFETs), the first and second strain-inducing source and drain structures 262, 264, 362, and 364 are made of a material that is able to induce compressive strain in the first and second channel regions 250 and 350. The compressive strain induced in the first and second channel regions 250 and 350 can enhance hole mobility in the first and second channel regions 250 and 350. In some embodiments, the first and second strain-inducing source and drain structures 262, 264, 362, and 364 are made of a material whose lattice constant is greater than that of the first and second channel regions 250 and 350 to induce compressive strain in the first and second channel regions 250 and 350. For example, when the first and second channel regions 250 and 350 are made of silicon, the first and second strain-inducing source and drain structures 262, 264, 362, and 364 are made of, for example, SiGe.

In the embodiments where the first and second transistors 200 and 300 are both n-channel metal-oxide-semiconductor field-effect transistors (n-channel MOSFETs), the first and second strain-inducing source and drain structures 262, 264, 362, and 364 are made of a material that is able to induce tensile strain in the first and second channel regions 250 and 350. The tensile strain induced in the first and second channel regions 250 and 350 can enhance electron mobility in the first and second channel regions 250 and 350. In some embodiments, the first and second strain-inducing source and drain structures 262, 264, 362, and 364 are made of a material whose lattice constant is less than that of the first and second channel regions 250 and 350 to induce tensile strain in the first and second channel regions 250 and 350. For example, when the first and second channel regions 250 and 350 are made of silicon, the first and second strain-inducing source and drain structures 262, 264, 362, and 364 are made of, for example, SiP or SiC.

Proximity of at least one of the first strain-inducing source and drain structures 262 and 264 to the first gate structure 210 is different from proximity of at least one of the second strain-inducing source and drain structures 362 and 364 to the second gate structure 310. In some embodiments, the proximity of at least one of the first strain-inducing source and drain structures 262 and 264 to the first gate structure 210 is less than the proximity of at least one of the second strain-inducing source and drain structures 362 and 364 to the second gate structure 310. That is, a distance from at least one of the first strain-inducing source and drain structures 262 and 264 to the first gate structure 210 is greater than a distance from at least one of the second strain-inducing source and drain structures 362 and 364 to the second gate structure 310. Furthermore, a distance between the first strain-inducing source and drain structures 262 and 264 is different from a distance between the second strain-inducing source and drain structures 362 and 364. In some embodiments, the distance between the first strain-inducing source and drain structures 262 and 264 is greater than the distance between the second strain-inducing source and drain structures 362 and 364.

Proximity of at least one of the first strain-inducing source and drain structures 262 and 264 to the first channel region 250 is different from proximity of at least one of the second strain-inducing source and drain structures 362 and 364 to the second channel region 350. In some embodiments, the proximity of at least one of the first strain-inducing source and drain structures 262 and 264 to the first channel region 250 is less than the proximity of at least one of the second strain-inducing source and drain structures 362 and 364 to the second channel region 350. That is, a distance from at least one of the first strain-inducing source and drain structures 262 and 264 to the first channel region 250 is greater than a distance from at least one of the second strain-inducing source and drain structures 362 and 364 to the second channel region 350.

These proximities and distances are correlated with characteristics and properties of the first and second transistors 200 and 300. The first and second transistors 200 and 300 may be of the same type. That is, the first and second transistors 200 and 300 are both p-channel metal-oxide-semiconductor field-effect transistors (p-channel MOSFETs). Alternatively, the first and second transistors 200 and 300 are both n-channel MOSFETs. However, the first and second transistors 200 and 300 may have different optimization needs.

For example, for the second transistor 300, the proximities of the second strain-inducing source and drain structures 362 and 364 to the second channel region 350 is reduced to have a relatively large transconductance and thus a large mobility. However, for an input/output or low power logic transistor, reducing the proximities of the strain-inducing source and drain structures to the gate structure may lead to large junction leakage and reliability issue. Therefore, for the first transistor 200, the proximities of the first strain-inducing source and drain structures 262 and 264 to the first channel region 250 are enlarged to improve junction leakage and reliability issue.

The embodiments disclosed herein offer optimization flexibility. For example, the first spacer widths FSW of the first spacers 232 and 234 and the second spacer widths SSW of the second spacers 332 and 334 may be individually adjusted so that the recesses 242, 244, 342, and 344 (shown in FIG. 6) may be formed closer or farther away from the first and second gate structures 210 and 310. The distances between the recesses 242, 244, 342, and 344 (shown in FIG. 6) and their respective first and second gate structures 210 and 310 affect (or are correlated to) the proximities of the first and second strain-inducing source and drain structures 262, 264, 362, and 364 to their respective first and second channel regions 250 and 350. In addition, the implantation process can be adjusted to tune the lateral etching rate of the implanted portions of the substrate. As such, the profiles and lateral extensions of the recesses 242, 244, 342, and 344 (shown in FIG. 6) may be individually controlled as well. This means that the locations and the shapes of the first and second strain-inducing source and drain structures 262, 264, 362, and 364 may be individually controlled as well.

The method of adjusting spacer thicknesses and the method of dopant selective etching discussed above may be used separately or in combination to individually adjust the proximities of the first and second strain-inducing source and drain structures 262, 264, 362, and 364 to their respective first and second channel regions 250 and 350. Thus, the first and second transistors 200 and 300 may be optimized based on their own functions. As an example, the second transistor 300 may be a high performance transistor. Thus, the proximities of the second strain-inducing source and drain structures 362 and 364 to the second channel region 350 are greater than the proximities of the first strain-inducing source and drain structures 262 and 264 to the first channel region 250. In other words, the second transistor 300 is optimized for high performance. In the manner outlined above, the embodiments disclosed herein allows for flexible optimization for different transistors that are on a single semiconductor device.

It is understood that for the embodiments shown above, additional processes may be performed to complete the fabrication of the semiconductor device. For example, these additional processes may include a replacement polysilicon gate (RPG) process, formation of self-aligned silicides (salicides), formation of contacts, formation of interconnect structures (e.g., lines and vias, metal layers, and interlayer dielectric that provide electrical interconnection to the semiconductor device), formation of passivation layers, and packaging of the semiconductor device.

According to some embodiments of the present disclosure, a semiconductor device includes a substrate, first strain-inducing source and drain structures, a first gate structure, a first channel region, second strain-inducing source and drain structures, a second gate structure, and a second channel region. The first strain-inducing source and drain structures are disposed at least partially in the substrate. The first gate structure is disposed on the substrate and between the first strain-inducing source and drain structures. The first channel region is disposed in the substrate and under the first gate structure. At least one of the first strain-inducing source and drain structures has a first proximity to the first channel region. The second strain-inducing source and drain structures are disposed at least partially in the substrate. The second gate structure is disposed on the substrate and between the second strain-inducing source and drain structures. The second channel region is disposed in the substrate and under the second gate structure. At least one of the second strain-inducing source and drain structures has a second proximity to the second channel region. The second proximity is different from the first proximity.

According to some embodiments of the present disclosure, a semiconductor device includes a substrate, first strain-inducing source and drain structures, a first channel region, a first gate structure, second strain-inducing source and drain structures, a second channel region, and a second gate structure. The first strain-inducing source and drain structures are disposed at least partially in the substrate. The first channel region is disposed in the substrate and between the first strain-inducing source and drain structures. The first gate structure is disposed over the first channel region. The first gate structure and at least one of the first strain-inducing source and drain structures are separated from each other by a first distance. The second strain-inducing source and drain structures disposed at least partially in the substrate. The second channel region is disposed in the substrate and between the second strain-inducing source and drain structures. The second gate structure is disposed over the second channel region. The second gate structure and at least one of the second strain-inducing source and drain structures are separated from each other by a second distance. The first distance is greater than the second distance.

According to some embodiments of the present disclosure, a method for manufacturing a semiconductor device includes the following steps. First and second gate structures are formed on a substrate. First and second strain-inducing source and drain structures are formed at least partially in the substrate. The forming the first and second strain-inducing source and drain structures is carry out in a manner so that the first gate structure is formed between the first strain-inducing source and drain structures, the first gate structure is separated from at least one of the first strain-inducing source and drain structures by a first distance, the second gate structure is formed between the second strain-inducing source and drain structures, the second gate structure is separated from at least one of the second strain-inducing source and drain structures by a second distance, and the first distance and the second distance are different from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first strain-inducing source and drain structures disposed at least partially in the substrate;
a first gate structure disposed on the substrate and between the first strain-inducing source and drain structures;
a first channel region disposed in the substrate and under the first gate structure, wherein at least one of the first strain-inducing source and drain structures has a first proximity to the first channel region;
second strain-inducing source and drain structures disposed at least partially in the substrate;
a second gate structure disposed on the substrate and between the second strain-inducing source and drain structures; and
a second channel region disposed in the substrate and under the second gate structure, wherein at least one of the second strain-inducing source and drain structures has a second proximity to the second channel region, and the second proximity is different from the first proximity.

2. The semiconductor device of claim 1, further comprising:
at least one first spacer disposed on at least one sidewall of the first gate structure; and
at least one second spacer disposed on at least one sidewall of the second gate structure, wherein the first spacer and the second spacer have different thicknesses.

3. The semiconductor device of claim 1, wherein the first strain-inducing source and drain structures are separated from each other by a first distance, the second strain-inducing source and drain structures are separated from each other by a second distance, and the second distance is different from the first distance.

4. The semiconductor device of claim 1, wherein the first strain-inducing source and drain structures, the first gate structure, and the first channel region are portions of a first transistor, the second strain-inducing source and drain structures, the second gate structure, and the second channel region are portions of a second transistor, and the first transistor and the second transistor are of the same type.

5. The semiconductor device of claim 1, wherein the first strain-inducing source and drain structures are made of a material that is able to induce compressive strain in the first channel region.

6. The semiconductor device of claim 5, wherein the second strain-inducing source and drain structures are made of a material that is able to induce compressive strain in the second channel region.

7. The semiconductor device of claim 1, wherein the first strain-inducing source and drain structures are made of a material that is able to induce tensile strain in the first channel region.

8. The semiconductor device of claim 7, wherein the second strain-inducing source and drain structures are made of a material that is able to induce tensile strain in the second channel region.

9. A semiconductor device, comprising:
a substrate;
first strain-inducing source and drain structures disposed at least partially in the substrate;
a first channel region disposed in the substrate and between the first strain-inducing source and drain structures;
a first gate structure disposed over the first channel region, wherein the first gate structure and at least one of the first strain-inducing source and drain structures are separated from each other by a first distance;
second strain-inducing source and drain structures disposed at least partially in the substrate;
a second channel region disposed in the substrate and between the second strain-inducing source and drain structures; and
a second gate structure disposed over the second channel region, wherein the second gate structure and at least one of the second strain-inducing source and drain structures are separated from each other by a second distance, and the first distance is greater than the second distance.

10. The semiconductor device of claim 9, further comprising:
at least one first spacer disposed on at least one sidewall of the first gate structure; and
at least one second spacer disposed on at least one sidewall of the second gate structure, wherein the first spacer has a width greater than that of the second spacer.

11. The semiconductor device of claim 9, wherein the first strain-inducing source and drain structures are separated from each other by a third distance, the second strain-inducing source and drain structures are separated from each other by a fourth distance, and the third distance is greater than the fourth distance.

12. The semiconductor device of claim 9, wherein the first strain-inducing source and drain structures, the first channel region, and the first gate structure are portions of a first transistor, the second strain-inducing source and drain structures, the second channel region, and the second gate structure are portions of a second transistor, and the first and second transistors are both p-channel metal-oxide-semiconductor field-effect transistors (p-channel MOSFETs).

13. The semiconductor device of claim 9, wherein the first strain-inducing source and drain structures are made of a material whose lattice constant is greater than that of the first channel region.

14. The semiconductor device of claim 13, wherein the second strain-inducing source and drain structures are made of a material whose lattice constant is greater than that of the second channel region.

15. The semiconductor device of claim 9, wherein the first strain-inducing source and drain structures, the first channel region, and the first gate structure are portions of a first transistor, the second strain-inducing source and drain structures, the second channel region, and the second gate structure are portions of a second transistor, and the first and second transistors are both n-channel metal-oxide-semiconductor field-effect transistors (n-channel MOSFETs).

16. The semiconductor device of claim 9, wherein the first strain-inducing source and drain structures are made of a material whose lattice constant is less than that of the first channel region.

17. The semiconductor device of claim 16, wherein the second strain-inducing source and drain structures are made of a material whose lattice constant is less than that of the second channel region.

18. A method for manufacturing a semiconductor device, the method comprising:
forming first and second gate structures on a substrate; and
forming first and second strain-inducing source and drain structures at least partially in the substrate, wherein the forming the first and second strain-inducing source and drain structures is carry out in a manner so that the first gate structure is formed between the first strain-inducing source and drain structures, the first gate structure is separated from at least one of the first strain-inducing source and drain structures by a first distance, the second gate structure is formed between the second strain-inducing source and drain structures, the second gate structure is separated from at least one of the second strain-inducing source and drain structures by a second distance, and the first distance and the second distance are different from each other.

19. The method of claim 18, further comprising:
forming at least one first spacer on at least one sidewall of the first gate structure and at least one second spacer on at least one sidewall of the second gate structure, wherein the first spacer and the second spacer have different thicknesses.

20. The method of claim 18, wherein the first and second strain-inducing source and drain structures are made of substantially the same material.
